(19) United States
(12) Patent Application Publication
(10) Pub. No.: US 2023/0163254 A1
(43) Pub. Date: May 25, 2023

(54) COLOR CONVERSION UNIT, COLOR CONVERSION STRUCTURE USING THE SAME, AND LIGHT-EMITTING DIODE DISPLAY USING THE SAME

(71) Applicant: INDUSTRIAL TECHNOLOGY RESEARCH INSTITUTE, Hsinchu (TW)

(72) Inventors: Kai-Ling LIANG, Hsinchu City (TW); Wei-Hung KUO, Hsinchu City (TW); Shinn-Jen CHANG, Hsinchu City (TW); Ruo-Han YU, Yilan City (TW)

(73) Assignee: INDUSTRIAL TECHNOLOGY RESEARCH INSTITUTE, Hsinchu (TW)

(21) Appl. No.: 17/564,769

(22) Filed: Dec. 29, 2021

(30) Foreign Application Priority Data
Nov. 24, 2021 (TW) 110143860

(51) Int. Cl. H01L 33/50; H01L 25/075

(52) U.S. Cl. CPC H01L 33/504; H01L 25/0753; H01L 2933/0041

(57) ABSTRACT

A color conversion unit is provided. The color conversion unit includes a substrate and a color conversion layer. The substrate includes a hole. The color conversion layer is embedded in the hole of the substrate, wherein a ratio of a width to a height of the color conversion layer is between 1:1 and 1:15, and a color conversion mixture used to form the color conversion layer is cured by excitation light wavelength between 385 nm 1180 nm. A micro light-emitting diode disposed under the color conversion layer is used to provide light to the color conversion layer.

This application claims the benefit of Taiwan application Serial No. 110143860. filed Nov. 24, 2021, the disclosure of which is incorporated by reference herein in its entirety.

### TECHNICAL FIELD

The disclosure relates in general to a color conversion unit, a color conversion structure using the same, and a light-emitting diode display using the same, and more particularly to a color conversion unit including micro light-emitting diodes, a color conversion structure using the same, and a light-emitting diode display using the same.

### BACKGROUND

Recently, the demands for micro light-emitting diode displays in the market have been gradually increased. The micro light-emitting diode display can include a color conversion layer and an array of micro light-emitting diodes, wherein the color conversion layer can convert the light provided by the micro light-emitting diode into a desired wavelength. However, since the size of the micro light-emitting diode is much smaller than the size of the light-emitting diode, the size of the corresponding color conversion layer also needs to be reduced accordingly. For example, the thickness of the color conversion layer may be greatly reduced, making the existing micro light-emitting diodes displays still have the problem of insufficient color conversion efficiency. Therefore, there is still a great need to develop an improved micro light-emitting diode display to overcome the above-mentioned problems.

### SUMMARY

According to an embodiment of the present disclosure, a color conversion unit is provided. The color conversion unit includes a substrate and a color conversion layer. The substrate includes a hole. The color conversion layer is embedded in the hole of the substrate, wherein a ratio of a width to a height of the color conversion layer is between 1:1 and 1:15, and a color conversion mixture used to form the color conversion layer is cured by excitation light wavelength between 385 nm and 1180 nm. A micro light-emitting diode disposed under the color conversion layer is used to provide light to the color conversion layer.

According to another embodiment of the present disclosure, a color conversion structure is proposed. The color conversion structure includes a plurality of color conversion units. The color conversion units include a substrate and a first color conversion layer, a second color conversion layer, and an optical cement adjacent to each other. The first color conversion layer, the second color conversion layer and the optical cement are respectively filled in a plurality of holes of the substrate. Emission wavelengths converted by the first color conversion layer, the second color conversion layer and the optical cement are different, and ratios of widths to heights of the first color conversion layer, the second color conversion layer and the optical cement are between 1:1 and 1:15, and color conversion mixtures used to form the first color conversion layer and the second color conversion layer are cured by excitation light wavelength between 385 nm and 1180 nm. A plurality of micro light-emitting diodes disposed under the first color conversion layer, the second color conversion layer and the optical cement are used to provide light to the first color conversion layer, the second color conversion layer and the optical cement.

According to a further embodiment of the present disclosure, a light-emitting diode display is provided. The light-emitting diode display includes a color conversion structure, an array of micro light-emitting diodes, and a backplane control structure. The color conversion structure includes a plurality of color conversion units, and the color conversion units include a substrate and a first color conversion layer, a second color conversion layer and an optical cement adjacent to each other. The substrate includes a plurality of holes. The first color conversion layer, the second color conversion layer and the optical cement are filled in the holes of the substrate. Emission wavelengths converted by the first color conversion layer, the second color conversion layer and the optical cement are different, and ratios of widths to heights of the first color conversion layer, the second color conversion layer and the optical cement is between 1:1 and 1:15, and color conversion mixtures used to form the first color conversion layer and the second color conversion layer are cured by excitation light wavelength between 385 nm and 1180 nm. The array of micro light-emitting diodes is disposed under the color conversion structure to provide light to the color conversion structure. The backplane control structure is disposed under the color conversion structure for controlling the array of micro light-emitting diodes.

In order to have a better understanding of the above and other aspects of the present disclosure, the following specific embodiments are given in conjunction with the accompanying drawings to describe in detail as follows.

### BRIEF DESCRIPTION OF THE DRAWINGS

FIGS. 1A to 1D show a flow chart for manufacturing a light-emitting diode display according to an embodiment of the present disclosure.

FIGS. 2A to 2G show a flow chart for manufacturing a light-emitting diode display according to a further embodiment of the present disclosure.

FIGS. 3A to 3H show a flow chart for manufacturing a light-emitting diode display according to a further embodiment of the present disclosure.

FIGS. 4A to 4C show a flow chart for manufacturing a reflecting structure according to an embodiment of the present disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

The present disclosure relates to a color conversion unit, a color conversion structure using the color conversion unit, and a light-emitting diode display using the color conversion unit. Compared with the existing micro light-emitting diode display, since the color conversion layers of the color conversion units, the color conversion structure and the light-emitting diode display used in the present disclosure have a higher aspect ratio, the color conversion layers can have a larger thickness, so the color conversion efficiency can be greatly improved. Moreover, compared with the comparative example that uses the black matrix to block light, since the color conversion layers of the present disclosure can be embedded in the holes of the substrate with a high aspect ratio, the substrate can effectively solve the problem of the cross-talk of light between the color conversion layers, and achieve a more excellent light blocking effect.

The following describes the implementations of the present disclosure in detail with reference to the accompanying drawings. It should be noted that the structure, manufacturing process, and content of the implementations proposed in the embodiments are for illustrative purposes only, and the scope to be protected by the present disclosure is not limited to the described implementations. It should be noted that the present disclosure does not show all possible embodiments, and those skilled in the art can change and modify the structure and manufacturing process of the embodiments without departing from the spirit and scope of the disclosure to meet actual requirements for applications.

Further, the same or similar reference numerals are used in the same or similar elements in the embodiments to facilitate clear description. In addition, the drawings have been simplified to clearly illustrate the content of the embodiments, and the sizes of elements in the drawings are not drawn in the same proportion related to the actual products, so they are not used to limit the protected scope of the present disclosure.

Furthermore, the ordinal numbers used in the specification and the scope of the present disclosure, such as the terms “first”, “second”, etc., are used to modify the elements in the scope of the present disclosure, and do not in themselves mean and represent any previous ordinal number of the claimed element, and does not represent the order of a certain claimed element and another claimed element, or the order of the manufacturing method. The use of these ordinal numbers is only used to enable a claimed element with a certain name to be clearly distinguished over another claimed element with the same name.

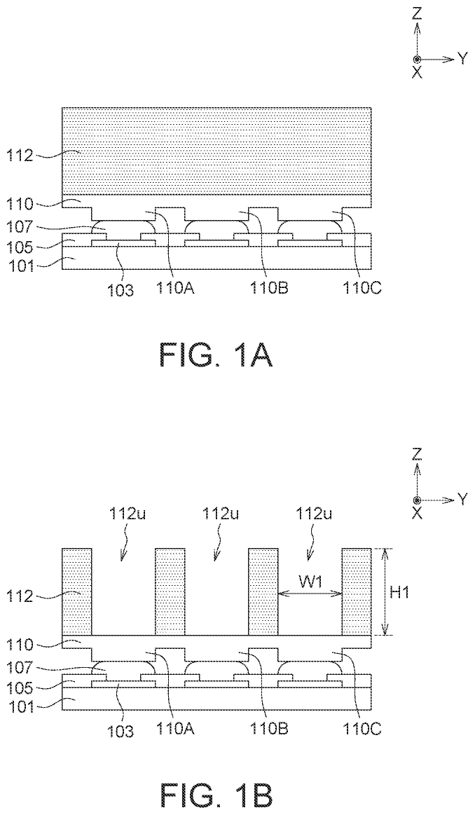

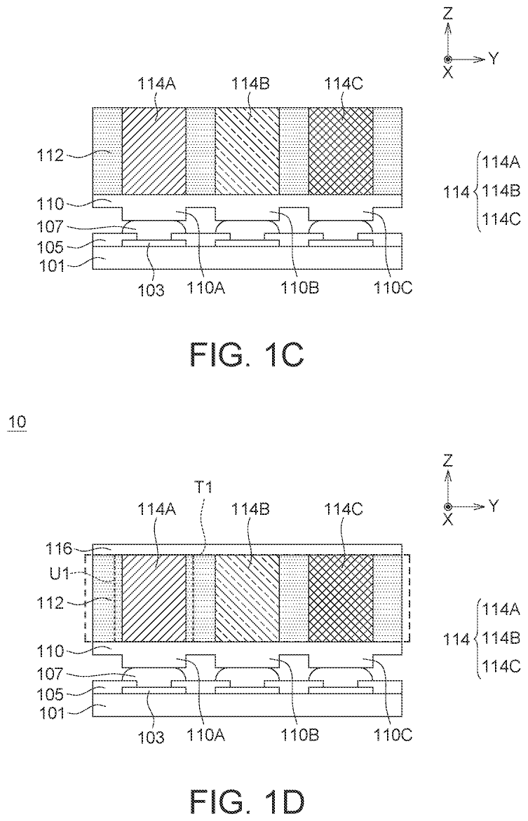

FIGS. 1A to 1D show a flow chart for manufacturing a light-emitting diode display 10 according to an embodiment of the present disclosure. FIGS. 1A to 1D may correspond to cross-sectional views formed in a second direction (for example, Y direction) and a third direction (for example, Z direction). The second direction may be perpendicular to the third direction.

First, referring to FIG. 1A, a backplane control structure 101, an array of micro light-emitting diodes 110, and a substrate 112 are provided. The array of micro light-emitting diodes 110 is disposed above the backplane control structure 101, and the substrate 112 is disposed above the array of micro light-emitting diodes 110. The backplane control structure 101 and the array of micro light-emitting diodes 110 are electrically connected to each other through contact pads 103 and bumps 107. The contact pads 103 are, for example, disposed in the insulating layer 105. The backplane control structure 101 may include a Complementary Metal-Oxide-Semiconductor (CMOS) layer, a transistor layer, or other suitable electronic driving layers. The substrate 112 is, for example, a silicon substrate, an epitaxial wafer, or other suitable substrates. In some embodiments, the substrate 112 may include an oxide layer (not shown). The array of micro-light-emitting diodes 110 may include a plurality of micro-light-emitting diodes 110A, 110B, 110C . . . which are arranged in a matrix, and each of the micro-light-emitting diodes 110A, 110B, 110C . . . can correspond to a sub-pixel.

Thereafter, referring to FIG. 1B, a plurality of holes 112u are formed on the substrate 112 through an etching process, and each of holes 112u corresponds to and exposes a micro light-emitting diode 110A, 110E or 110C . . . . That is, in the top view, holes 112u are arranged in a matrix (not shown) corresponding to the micro light emitting diodes. In the present embodiment, the micro light-emitting diodes 110A, 110B, and 110C can correspond to three sub-pixels of different colors in one pixel, respectively, but the present disclosure is not limited thereto. According to an embodiment, the etching process is, for example, a dry etching process. A ratio (i.e., W1:H1) of a width W1 (for example, the maximum width) to a height H1 (for example, the maximum height) of the hole 112u is, for example, between 1:1 and 1:15. In some embodiments, the ratio of the width W1 to the height H1 of the hole 112u is, for example, between 1:5 and 1:15, between 1:7 and 1:15, between 1:8 and 1:13, or in other suitable ranges.

After the holes 112u are formed, referring to FIG. 1C, fill the holes 112u with color conversion mixtures. The color conversion mixtures are used to form the color conversion layers 114. For example, after the exposure step, the color conversion mixtures can be cured into the color conversion layers 114. In the present embodiment, the ultraviolet light (e.g. 385 nm to 440 nm of the wavelength) is used for irradiation in the exposure step, but the present disclosure is not limited thereto. In other embodiments, near-infrared light (e.g. 780 nm to 820 nm of the wavelength), infrared light (e.g. 1030 nm to 1080 nm of the wavelength) or other suitable excitation light can be used for the irradiation in the exposure step.

The color conversion layers 114 may include a first color conversion layer 114A, a second color conversion layer 114B, and an optical cement 114C. The optical cement 114C may include scattering particles, and the present disclosure is not limited thereto. In the present embodiment, the micro light-emitting diodes 110A, 110B, 110C . . . are blue light micro light-emitting diodes. In one pixel, the color conversion mixtures can correspond to a red sub-pixel, a green sub-pixel, and a blue sub-pixel, respectively. However, the present disclosure is not limited thereto. In other embodiments, the color conversion mixtures may correspond to sub-pixels of other colors, such as the yellow sub-pixel, the purple sub-pixel, or the other sub-pixel in suitable color. According to the present embodiment, the color conversion mixture corresponding to the red sub-pixel includes a quantum dot material that can release a red spectrum, a photoresist, a photoinitiator, and other suitable materials. The color conversion mixture corresponding to the green sub-pixel includes quantum dot materials that can release the green spectrum, photoresist, photoinitiator, and other suitable materials. The material corresponding to the blue sub-pixel may include a scattering material, a photoresist, a photoinitiator, air, and other suitable materials, and may not include a color conversion mixture. That is, in the present embodiment, the first color conversion layer 114A includes a quantum dot material that can release a red spectrum, the second color conversion layer 114B includes a quantum dot material that can release a green spectrum, and the optical cement 114C does not include the color conversion mixture. In other embodiments, the micro light-emitting diode is a blue micro light-emitting diode, so the blue sub-pixel may not include the color conversion mixture. The solid content of the quantum dot materials is in between 10 wt % to 40 wt %, and the viscosity of the quantum dot materials is in between 5 cP to 90 cP. The scattering material is, for example, titanium dioxide (TiO₂), organic scattering particles or other suitable scattering materials. In the embodiment where ultraviolet light is used as the excitation light (that is, for curing the color conversion mixture), the color conversion mixture used to form the color conversion layer 114 may be cured between 385 nm and 440 nm, between 395 nm and 405 nm, between 400 nm and 420 nm, or in other suitable ranges of the excitation light wavelength.

In some embodiments that use ultraviolet light to cure the color conversion mixture (e.g. 385 nm to 440 nm of the excitation light wavelength that cures the color conversion mixture), the photoinitiator may be a compound without a nitrogen atom, such as 2-hydroxy-2-methylpropiophenone, diphenyl(2,4,6-trimethylbenzoyl)-phosphine oxide, 9,10-dibutoxyanthracene, 9,10-diethoxyanthracene, phenylbis(2,4,6-trimethylbenzoyl)phosphine oxide, benzophenone, or the arbitrary combination of the above.

In some embodiments using near-infrared light to cure the color conversion mixture, the color conversion mixture is cured, for example, between 700 nm and 950 nm, between 700 nm and 850 nm, between 800 nm and 950 nm, or in other suitable ranges of the excitation light wavelength.

In some embodiments using near-infrared light to cure the color conversion mixture (e.g. 700 nm to 850 nm of the excitation light wavelength that cures the color conversion mixture), the photoinitiator may be bisdialkylamino-substituted diphenylpolyene, bisdiarylamino-substituted diphenylpolyene, bis(styryl)benzene, or the arbitrary combination of the above, for example, the chemical formula of the photoinitiator can be as shown in the following Formula 1 to Formula 8:

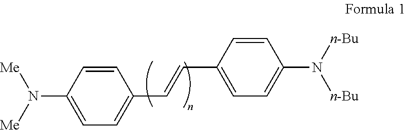

In Formula 1, “Me” represents a methyl group, “n-Bu” represents an n-butyl group, and “n” represents an integer of 3 to 5. The wavelength of light absorption of the photoinitiator shown in Formula 1 is, for example, 710 nm to 730 nm.

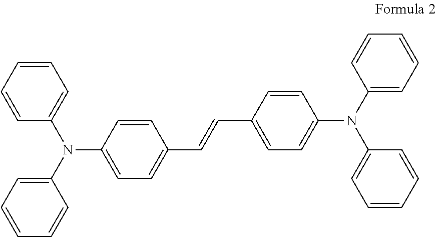 [SMILES: C(=C\c1ccc(N(c2ccccc2)c2ccccc2)cc1)/c1ccc(N(c2ccccc2)c2ccccc2)cc1]

In Formula 2, the wavelength of light absorption of the photoinitiator shown in Formula 2 is, for example, 670 nm to 690 nm.

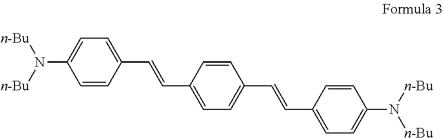

In Formula 3, “n-Bu” represents an n-butyl group.

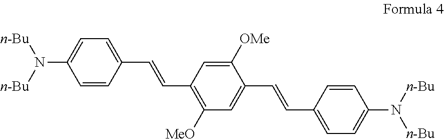

In Formula 4, “n-Bu” represents an n-butyl group, and “Me” represents a methyl group.

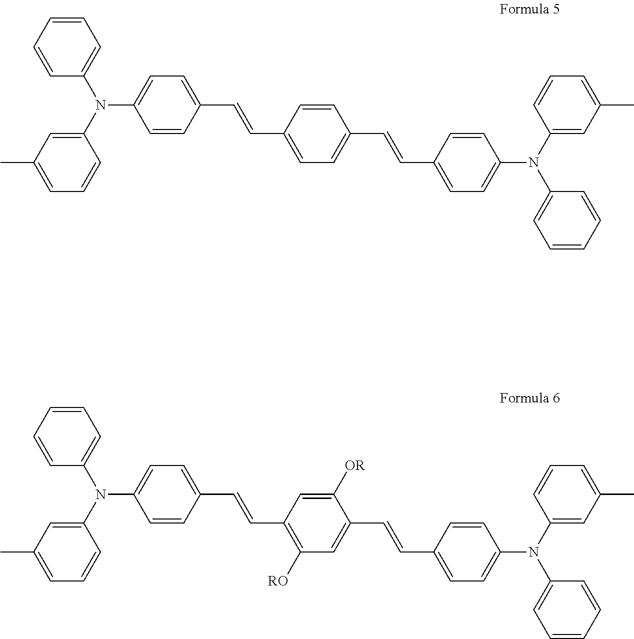

In Formula 6, “R” represents C₁₂H₂₅.

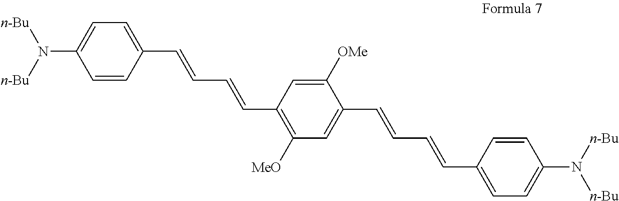

In Formula 7, “n-Bu” represents an n-butyl group, and “Me” represents a methyl group.

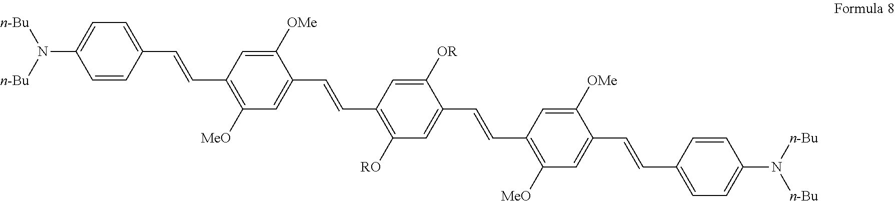

In Formula 8, “R” represents C₁₂H₂₅.

In some embodiments of using near-infrared light to cure the color conversion mixture (e.g. 800 nm to 950 nm of the excitation light wavelength that cures the color conversion mixture), the photoinitiator may be donor-acceptor-donor distyrylbenzene, wherein the donor can be di-n-butyl, diphenylamino or other suitable donor groups, and the acceptor can be cyano or other suitable acceptor groups; for example, the chemical formula of the photoinitiator can be as shown in the following Formula 9 to Formula 13:

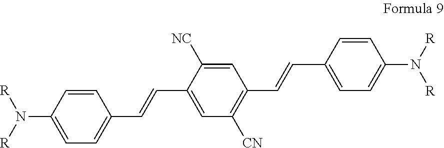

In Formula 9, “R” represents n-butyl or methyl. The wavelength of absorption light of the photoinitiator shown in Formula 9 is, for example, 830 nm.

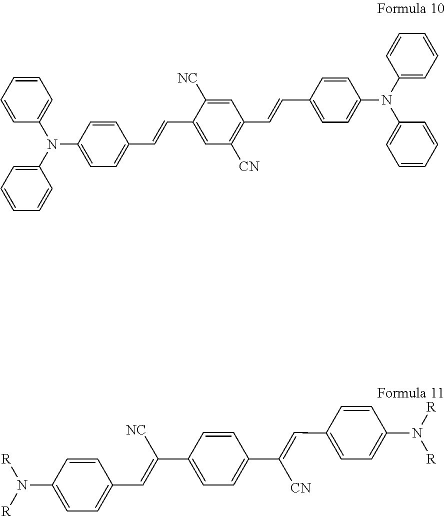

In Formula 11, “R” represents n-butyl or methyl. The wavelength of absorption light of the photoinitiator shown in Formula 11 is, for example, 800 nm.

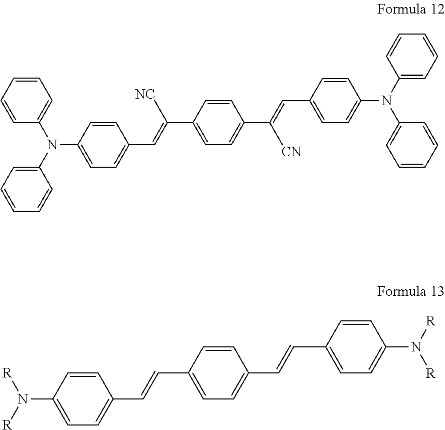

In Formula 13, “R” represents n-butyl or methyl. The wavelength of absorption light of the photoinitiator shown in Formula 13 is, for example, 730 nm.

In some embodiments using the infrared light to cure the color conversion mixture (e.g. 1030 nm to 1180 nm of the excitation light wavelength that cures the color conversion mixture), the photoinitiator can be squaraine, cyanine or other suitable ingredients; for example, the chemical formula of the photoinitiator can be as shown in the following Formula 14 to Formula 15:

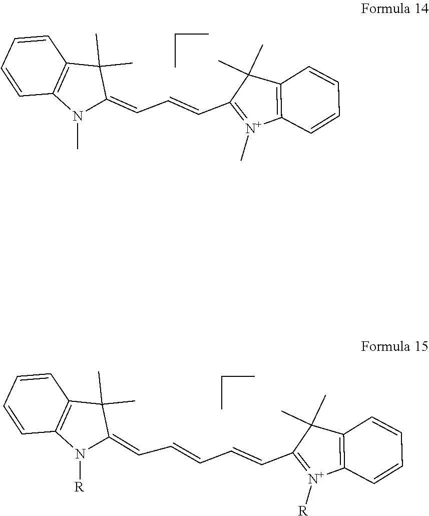

In Formula 15, “R” represents CH₃ or C₃H₇.

According to some experimental data using ultraviolet light as the excitation light, it is known that the emission intensity of the color conversion mixture when absorbing the light from a light source of 365 nm is greater than the emission intensity of the color conversion mixture when absorbing the light from a light source of 385 nm. Therefore, the degree of absorption in the color conversion mixture for the light from the light source of 365 nm is greater than the degree of absorption in the color conversion mixture for the light from the light source of 385 nm, that is, the light from light source of 365 nm has a greater influence on the optical properties of the color conversion mixture. It should be noted that in the color conversion mixture of the present disclosure, the formula of the photoinitiator can be adjusted according to the light absorption spectrum or light emission spectrum of the quantum dot material. For example, the quantum dot material has a first main absorption band for ultraviolet light (for example, 365 nm), the photoinitiator has a second main absorption band for ultraviolet light (for example, greater than 365 nm), and most of the second main absorption band is different from the first main absorption band. That is, in the color conversion mixture, a photoinitiator that avoids the main light absorption band of the quantum dot material should be selected to prevent a large part of the exposed light from being absorbed by the quantum dot material during the exposure step, and the color conversion mixture can only be cured by a part of the light, resulting in that the color conversion mixture cannot be cured completely. Especially, when a color conversion layer 114 with a large thickness (that is, a high aspect ratio) is formed, the color conversion mixture at the bottom is less likely to absorb the exposed light and is difficult to be cured. If the amount of exposure is increased in order to make the color conversion mixture to be cured in a more complete way, it may cause the quantum dot material to be damaged by the excitation light. Compared with the comparative example in which the excitation light wavelength that cures the color conversion mixture greatly overlaps the main absorption band of the quantum dot material, since the excitation light wavelength that cures the color conversion mixture to form the color conversion layer 114 according to an embodiment of the present disclosure is between 385 nm and 1180 nm, most range of the excitation light wavelength that cures the color conversion mixture is different from the main absorption wavelength of the quantum dot material (for example, the excitation light wavelength that cures the color conversion mixture is greater than the main absorption wavelength of the quantum dot), which can prevent the absorption of the quantum dots from affecting the color conversion mixture to be cured into a film. This solves the problem of incomplete curing of the color conversion mixture. In addition, when the excitation light having a longer wavelength is used to cure the color conversion mixture, the excitation light having a longer wavelength can have stronger penetrating ability, which is beneficial to form the color conversion layer 114 with a larger thickness. The color conversion layer 114 with a larger thickness of film may have more excellent color conversion efficiency.

In the present embodiment, the micro light-emitting diodes 110A, 110B, 110C . . . are blue light micro light-emitting diodes. After the emitted blue light is transmitted to the first color conversion layer 114A, the second color conversion layer 114B and the optical cement 114C, the emitted blue light is converted into red light and green light through the first color conversion layer 114A and the second color conversion layer 114B, respectively; since the optical cement 114C does not include the color conversion mixture, the blue light is directly transmitted through the optical cement 114C and appears as blue light. That is, the first color conversion layer 114A, the second color conversion layer 114B, and the optical cement 114C can respectively correspond to the red sub-pixel, the green sub-pixel, and the blue sub-pixel. However, the present disclosure is not limited thereto. In other embodiments, the first color conversion layer 114A, the second color conversion layer 114B, and the optical cement 114C can respectively correspond to sub-pixels of other colors.

After the color conversion layer 114 is formed, the color conversion layer 114 and the substrate 112 may be covered by a sealing layer 116 to form the light-emitting diode display 10 as shown in FIG. 1D. The light-emitting diode display 10 includes a color conversion structure T1, an array of micro light-emitting diodes 110, and a backplane control structure 101. The array of micro light-emitting diodes 110 is disposed under the color conversion structure T1, and is used to provide light to the color conversion structure T1. The backplane control structure 101 is disposed under the color conversion structure T1 for controlling the array of micro light-emitting diodes 110.

In the present embodiment, the color conversion structure T1 corresponds to a pixel including, for example, a red sub-pixel, a green sub-pixel, and a blue sub-pixel, but the present disclosure is not limited thereto. The array of micro light-emitting diodes 110 includes a plurality of micro light-emitting diodes 110A, 110B, 110C . . . arranged in a matrix. The color conversion structure T1 includes a plurality of color conversion units U1. The color conversion units U1 include a substrate 112 and a first color conversion layer 114A, a second color conversion layer 114B, and an optical cement 114C adjacent to each other. The substrate 112 includes a plurality of holes 112u. The holes 112u correspond to the micro light-emitting diodes 110A, 110B, and 110C, respectively. The first color conversion layer 114A, the second color conversion layer 114E and the optical cement 114C are filled in the holes 112u of the substrate 112. The emission wavelengths converted by the first color conversion layer 114A, the second color conversion layer 114B, and the optical cement 114C are different from each other. The micro light-emitting diodes 110A, 110B, 110C . . . disposed under the first color conversion layer 114A, the second color conversion layer 114B and the optical cement 114C are used to provide light to the first color conversion layer 114A, the second color conversion layer 114B and the optical cement 114C. The sealing layer 116 and the array of micro light-emitting diodes 110 may be disposed on opposite sides of the color conversion layer 114.

The ratios of widths to heights of the first color conversion layer 114A, the second color conversion layer 114B, and the optical cement 114C are between 1:1 and 1:15, between 1:7 and 1:15, between 1:8 and 1:13 or in other suitable range. Moreover, when the ultraviolet light is used for curing, the color conversion mixture used to form the first color conversion layer 114A and the second color conversion layer 114B is cured by excitation light wavelength between 385 nm and 440 nm. In other embodiments, when the optical cement 114C includes the color conversion mixture, the color conversion mixture is cured by excitation light wavelength between 385 nm and 440 nm. In some embodiments, the thickness of the first color conversion layer 114A, the second color conversion layer 114B, and the optical cement 114C can be between 2 μm and 20 μm, between 5 μm and 15 μm, between 7 μm and 12 μm, or in other suitable range. In the present embodiment, the thickness of the first color conversion layer 114A, the second color conversion layer 114B, and the optical cement 114C may be 5.5 μm, and the color conversion efficiency (CCE) of the first color conversion layer 114A and the second color conversion layer 114B can reach 50%. In a comparative example, the thickness of the first color conversion layer, the second color conversion layer, and the optical cement is 1.5 μm, and the color conversion efficiency of the first color conversion layer and the second color conversion layer is only 10%. It can be seen that the thickness of the color conversion layer 114 in the present disclosure is relatively large, which can greatly improve the color conversion efficiency.

Compared with the comparative example in which the excitation light wavelength that cures the color conversion mixture greatly overlaps the main absorption wavelength of the quantum dot material, since the excitation light wavelength that cures the color conversion mixture in the light-emitting diode display 10 of the present disclosure is between 385 nm and 1180 nm, which is greater than the main absorption wavelength of the quantum dot material, that is, the range of the excitation light wavelength that cures the color conversion mixture in the present disclosure is different from the main absorption wavelength of the quantum dot material, which can prevent the light absorption of the quantum dots from affecting the color conversion mixture to be cured into a film. Therefore, the formed color conversion layer 114 can have a good quality in curing. Moreover, it is beneficial in the present disclosure to form the color conversion layer 114 with a high aspect ratio (that is, a larger thickness) without a large amount of exposure. On the one hand, it can reduce the damage and degradation of the quantum dot material during exposure and improve the efficiency of the quantum dot; on the other hand, the color conversion layer 114 can have a sufficient thickness of the film to exhibit the color conversion efficiency to be more excellent. In addition, if the black matrix is disposed between the color conversion layers to block the light, the black matrix is limited by the process conditions, and the thickness of the black matrix is not large enough to effectively block the light; therefore, in comparison with the comparative example that the black matrix is disposed between the color conversion layers to block the light, since the color conversion layers 114 with sufficient thickness (for example, high aspect ratio) in the present disclosure can be embedded in the holes 112u of the substrate 112, the substrate 112 can surround the color conversion layers 114 and is disposed between the color conversion layers 114, the substrate 112 has an excellent effect for blocking the light, and can solve the problem of the cross-talk of light, accordingly.

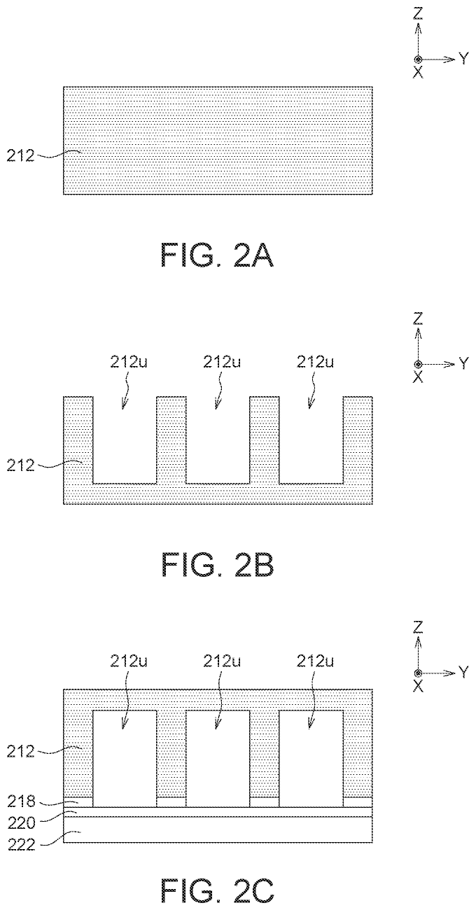

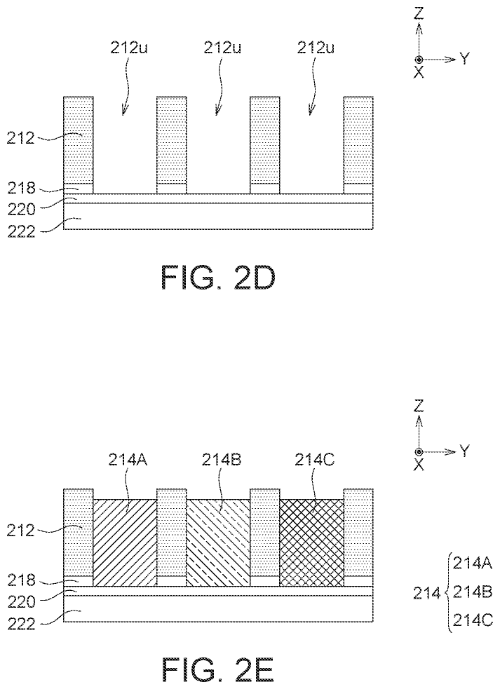

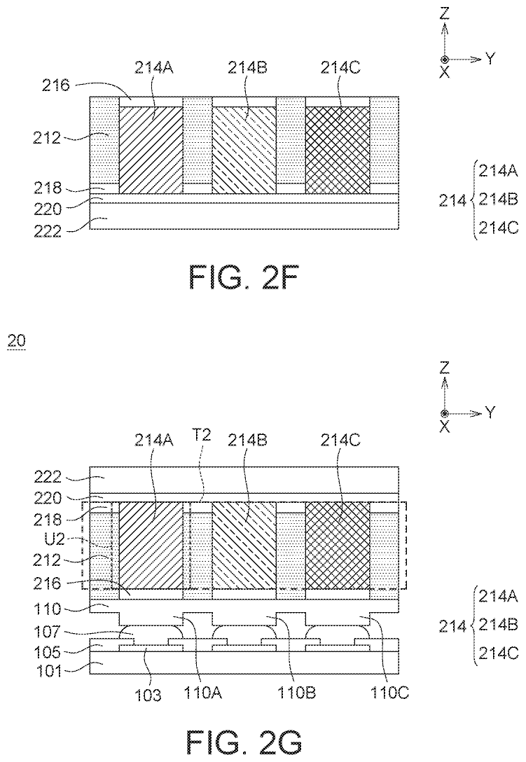

FIGS. 2A to 2G show a flow chart for manufacturing a light-emitting diode display 20 according to a further embodiment of the present disclosure. FIGS. 2A to 2G may correspond to cross-sectional views formed in the second direction (for example, Y direction) and the third direction (for example, Z direction). The elements in the light-emitting diode display 20 that are similar or identical to those of the light-emitting diode display 10 use the similar or identical reference numerals, and both have similar or identical physical and chemical properties, forming materials, forming methods, structures and functions. The repetition will not be described in detail.

First, referring to FIG. 2A, a substrate 212 is provided. The substrate 212 is, for example, a silicon substrate, an epitaxial wafer, or other suitable substrates. In some embodiments, the substrate 212 may include an oxide layer (not shown).

Thereafter, referring to FIG. 2B, a plurality of holes 212u are formed on the substrate 212 by an etching process, and each of the holes 212u corresponds to a predetermined position of a micro light-emitting diode (shown in FIG. 2G). According to an embodiment, the etching process is, for example, a dry etching process. The ratio of the width to the height of the hole 212u is, for example, between 1:1 and 1:15. In some embodiments, the ratio of the width to the height of the hole 212u is, for example, between 1:5 and 1:15, between 1:7 and 1:15, between 1:8 and 1:13, or in other suitable ranges.

After the holes 212u are formed, as shown in FIG. 2C, the substrate 212 is bonded to a cover plate 222 having a mirror structure 220 by an adhesive 218. The mirror structure 220 is, for example, a distributed Bragg reflector. The cover plate 222 is, for example, a glass cover plate or other suitable transparent cover plates.

Thereafter, referring to FIG. 2D, portions of the substrate 212 are removed by an etching process and the holes 212u are exposed. The holes 212u can expose portions of the mirror structure 220.

As shown in FIG. 2E, the color conversion mixture is filled into the holes 212u to form the color conversion layer 214. The color conversion layer 214 may include a first color conversion layer 214A, a second color conversion layer 214B, and an optical cement 214C. The materials and functions of the first color conversion layer 214A, the second color conversion layer 214B and the optical cement 214C may be the same as those of the first color conversion layer 114A, the second color conversion layer 114B, and the optical cement 114C, respectively.

After filling the color conversion mixture, referring to FIG. 2F, a sealing layer 216 may be formed on the color conversion layers 214 and the substrate 212.

Thereafter, referring to FIG. 2G, the sealing layer 216 is bonded to the array of micro light-emitting diodes 110 which is electrically connected to the backplane control structure 101 by flip bonding to form the light-emitting diode display 20. The light-emitting diode display 20 includes a color conversion structure T2, an array of micro light-emitting diodes 110, and a backplane control structure 101. The array of micro light-emitting diodes 110 is disposed under the color conversion structure T2, and is used to provide the light to the color conversion structure T2. The backplane control structure 101 is disposed under the color conversion structure T2 for controlling the array of micro light-emitting diodes 110.

In the present embodiment, the color conversion structure T2 corresponds to, for example, a pixel including a red sub-pixel, a green sub-pixel, and a blue sub-pixel, but the present disclosure is not limited thereto. The color conversion structure T2 includes a plurality of color conversion units U2. The color conversion unit U2 includes a substrate 212 and a first color conversion layer 214A, a second color conversion layer 214B, and an optical cement 214C adjacent to each other. The sealing layer 216 and the mirror structure 220 may be disposed on opposite sides of the color conversion layer 214. Moreover, the sealing layer 216 is closer to the array of micro light-emitting diodes 110 than the mirror structure 220. The cover plate 222 is disposed on the mirror structure 220, the substrate 212 and the color conversion layers 214.

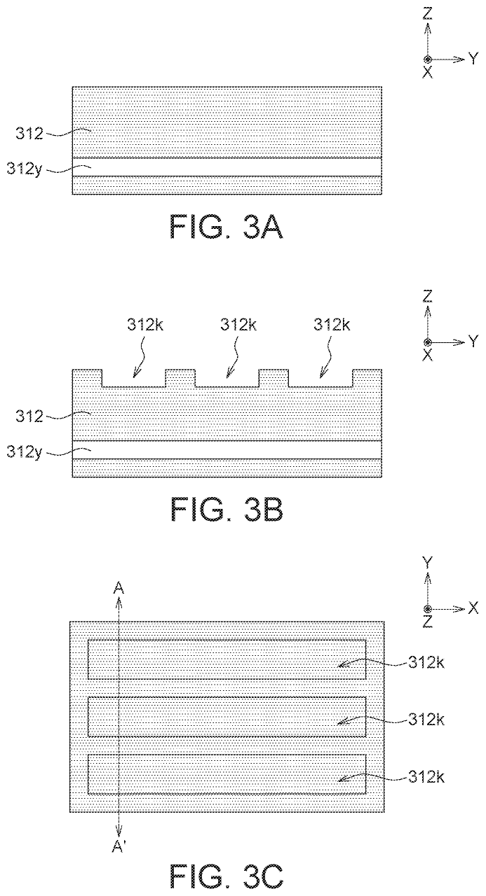

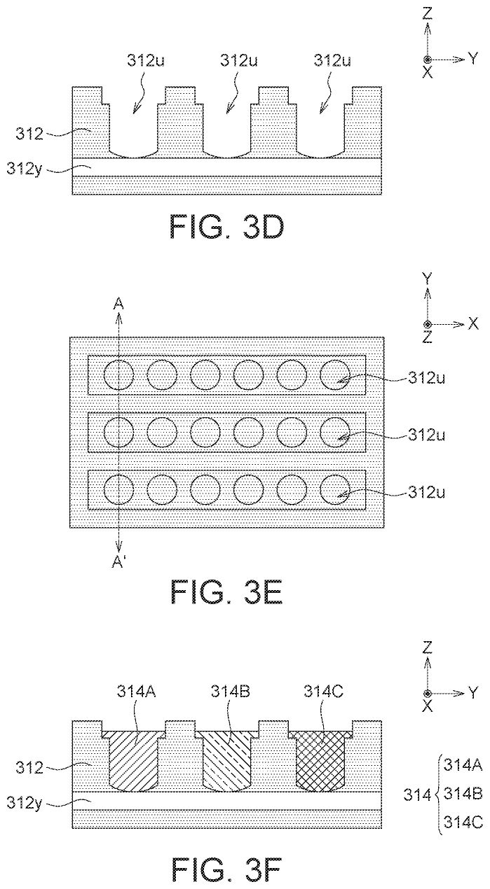

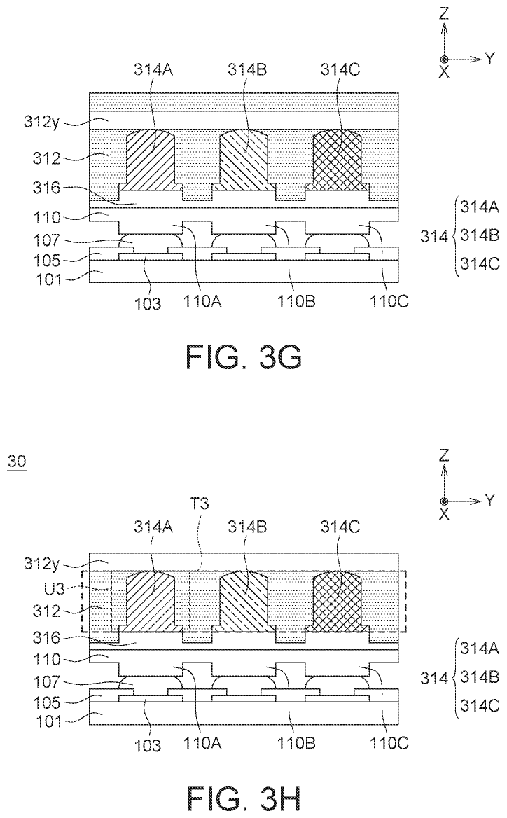

FIGS. 3A to 3H show a flow chart for manufacturing a light-emitting diode display 30 according to a further embodiment of the present disclosure, FIGS. 3A, 3B, 3D, and 3F to 3H are cross-sectional views of the manufacturing process of the light-emitting diode display 30, which correspond to cross-sectional views formed by the second direction (for example, Y direction) and the third direction (for example, Z direction). FIG. 3C shows a top view corresponding to FIG. 3B, that is, FIG. 3B is a cross-sectional view taken along the line A-A′ of FIG. 3C; FIG. 3E shows a top view corresponding to FIG. 3D, that is, FIG. 3D is a cross-sectional view taken along the line A-A′ of FIG. 3E. For example, FIGS. 3C and 3E correspond to the plane formed by the first direction (for example, X direction) and the second direction (for example, Y direction), and the first direction, the second direction and the third direction may be perpendicular to each other. The elements of the light-emitting diode display 30 that are similar or identical to those of the light-emitting diode display 10 use similar or identical reference numerals, and both have similar or identical physical and chemical properties, forming materials, structures, and functions, and the repetition will not be described in detail.

First, referring to FIG. 3A, a substrate 312 is provided. The substrate 312 may include an oxide layer 312y. The substrate 312 is, for example, a silicon substrate, an epitaxial wafer, or other suitable substrates. The material of the oxide layer 312y is, for example, silicon oxide.

Thereafter, referring to FIGS. 3B and 3C at the same time, a plurality of trenches 312k are formed on the substrate 312 by an etching process. The trenches 312k extend in a first direction (for example, X direction), and are separated from each other in a second direction (for example, Y direction). In other words, the trenches 312k can be separated by the substrate 312.

After forming the trenches 312k, referring to FIGS. 3E and 3D at the same time, a plurality of holes 312u on the substrate 312 are formed by an etching process. Each of the holes 312u corresponds to a predetermined position of a micro light-emitting diode (as shown in FIG. 3G). The hole 312u communicates with the corresponding one of the trenches 312k. According to an embodiment, the etching process is, for example, a dry etching process. The ratio of the width to the height of the hole 312u is, for example, between 1:1 and 1:15. In some embodiments, the ratio of the width to the height of the hole 312u is, for example, between 1:5 and 1:15, between 1:7 and 1:15, between 1:8 and 1:13 or in other suitable ranges.

After forming the holes 312u, as shown in FIG. 3F, the color conversion mixture is filled into the holes 312u by an inkjet printing process to form the color conversion layers 314. The color conversion layers 314 may include a first color conversion layer 314A, a second color conversion layer 314B, and an optical cement 314C. The materials and functions of the first color conversion layer 314A, the second color conversion layer 314B, and the optical cement 314C may be similar to those of the first color conversion layer 114A, the second color conversion layer 114B, and the optical cement 114C, respectively.

After that, referring to FIG. 3G, the sealing layer 316 can be covered on the color conversion layer 314 and the substrate 312, and the sealing layer 316 can be bonded to the array of micro light-emitting diodes 110 which is electrically connected to the backplane control structure 101 by the flip bonding,

Referring to FIG. 3H, a portion of the substrate 312 is removed and the oxide layer 312y is exposed to form a light-emitting diode display 30. The light-emitting diode display 30 includes a color conversion structure T3, an array of micro light-emitting diodes 110, and a backplane control structure 101 The array of micro light-emitting diodes 110 is disposed under the color conversion structure T3, and is used to provide light to the color conversion structure T3. The backplane control structure 101 is disposed under the color conversion structure T3 for controlling the array of micro light-emitting diodes 110.

In the present embodiment, the color conversion structure T3 corresponds to, for example, a pixel including a red sub-pixel, a green sub-pixel, and a blue sub-pixel, but the present disclosure is not limited thereto. The color conversion structure T3 includes a plurality of color conversion units U3. The color conversion units U3 include a substrate 312 and a color conversion layer 314 (i.e., a first color conversion layer 314A, a second color conversion layer 314B, and an optical cement 3140 adjacent to each other). The sealing layer 316 and the oxide layer 312y may be disposed on opposite sides of the color conversion layer 314. The oxide layer 312y is disposed above the color conversion layer 314. The sealing layer 316 is closer to the array of micro light-emitting diodes 110 than the oxide layer 312y.

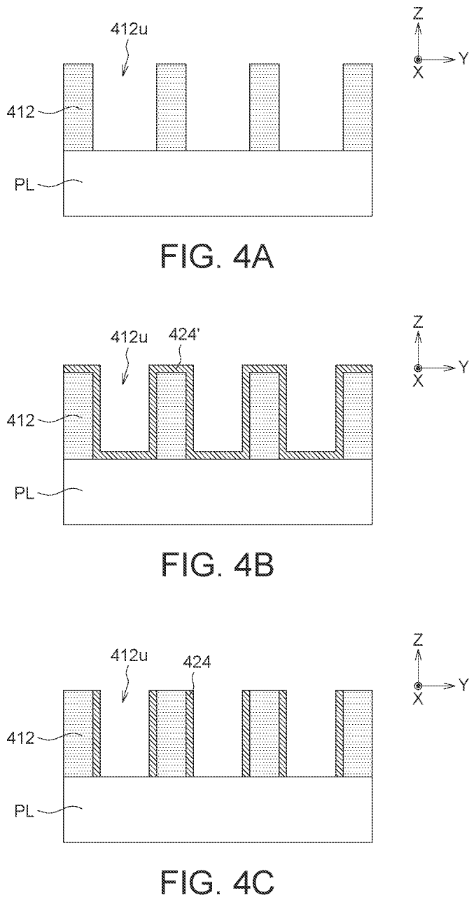

FIGS. 4A to 4C show a flow chart for manufacturing a reflecting structure 424 according to an embodiment of the present disclosure. The reflecting structure 424 can be applied to the light-emitting diode displays 10 to 30 as described above or other suitable light-emitting diode displays.

Referring to FIG. 4A, a plurality of holes 412u are formed in the substrate 412. The substrate 412 is, for example, disposed on a specific structure PL. When the present the embodiment is applied to the embodiment of the light-emitting diode display 10, the specific structure PL is, for example, the array of micro light-emitting diode 110 as shown in FIG. 1B; when the present the embodiment is applied to the embodiment of the light-emitting diode display 20, the specific structure PL is, for example, a cover plate 222 having the mirror structure 220 as shown in FIG. 2D; when the present the embodiment is applied to an embodiment of a light-emitting diode display 30, the specific structure PL is, for example, the oxide layer 312y in the substrate 312 as shown in FIG. 3D.

After the holes 412u are formed, referring to FIG. 4B, a reflective layer 424′ conformal to the holes 412u and the substrate 412 is formed by a sputtering process. The material of the reflective layer 424′ is, for example, the metal material, a distributed Bragg reflector or other suitable materials. The metal material can be selected from gold, silver, aluminum, copper, titanium or the arbitrary combination thereof. The distributed Bragg reflector is a material known to those ordinary skilled in the art, and may be a stack of oxide/metal oxide, for example.

After that, referring to FIG. 4C, the reflective layer 424′ disposed at the bottom of the holes 412u and disposed on the substrate 412 are removed by an etch-back process, and the reflective layer 424′ disposed on the sidewalls of the holes 412u is remained to form reflecting structures 424. That is, the reflecting structures 424 are disposed on the sidewalls of the holes 412u (for example, the holes 112u, 212u, or 312u in the light-emitting diode display 10 to 30), and are disposed between the color conversion layer (for example, the color conversion layer 114, 214, or 314) and the substrate 412 (for example, the substrate 112, 212, or 312). In some embodiments, a thickness of the reflecting structures 424 may be 1000 angstroms to 2000 angstroms, and a pitch may be 1.5 μm.

In some embodiments, the embodiments of the light-emitting diode displays 10 to 30 can be combined arbitrarily, or the light-emitting diode displays 10 to 30 can be combined with other embodiments. According to some embodiments, a color filter (not shown) may be disposed on the color conversion layers 114, 214, or 314. For example, a color filter (not shown) may be disposed between the color conversion layers 214 and the mirror structure 220.

In summary, according to an embodiment of the present disclosure, a color conversion unit is provided. The color conversion layer is filled in a hole of the substrate, wherein a ratio of a width to a height of the color conversion layer is between 1:1 and 1:15, and the color conversion mixture used to form the color conversion layer is cured by excitation light wavelength between 385 μm and 1180 μm.

Compared with the comparative example where the ratio of the width to the height of the color conversion layer is 1:0.4, since the ratio of the width to the height of the color conversion layer in an embodiment of the present disclosure is between 1:1 and 1:15, the color conversion layer has a relatively large thickness, so the color conversion efficiency can be improved.

Compared with the comparative example in which the excitation light wavelength that cures the color conversion mixture to form the color conversion layer is 365 nm, since the excitation light wavelength of the present disclosure is between 385 nm and 1180 nm, the excitation light wavelength that cures the color conversion mixture is different from the main absorption wavelength of the quantum dot material, which can prevent the light absorption of the quantum dots from affecting the curing of the color conversion mixture into a film, so the formed color conversion layer can have a good quality in curing. Moreover, the present disclosure is beneficial for forming a color conversion layer with a high aspect ratio (that is, a larger thickness) without a large amount of exposure. On the one hand, it can reduce the damage and degradation of the quantum dot material during exposure and improve the efficiency of the quantum dot; on the other hand, the color conversion layer can have a sufficient film thickness to exhibit the color conversion efficiency to be more excellent.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A color conversion unit, comprising:
a substrate, comprising a hole; and
a color conversion layer, embedded in the hole of the substrate, wherein a ratio of a width to a height of the color conversion layer is between 1:1 and 1:15, and a color conversion mixture used to form the color conversion layer is cured by excitation light wavelength between 385 nm and 1180 nm; wherein a micro light-emitting diode disposed under the color conversion layer is used to provide light to the color conversion layer.

2. The color conversion unit according to claim 1, wherein the substrate comprises an oxide layer.

3. The color conversion unit according to claim 1, further comprising a reflecting structure disposed on a sidewall of the hole and disposed between the color conversion layer and the substrate.

4. The color conversion unit according to claim 1, wherein the color conversion layer comprises a quantum dot material, a photoresist, and a photoinitiator.

5. A color conversion structure, comprising:
a plurality of color conversion units comprising a substrate and a first color conversion layer, a second color conversion layer and an optical cement adjacent to each other, the first color conversion layer, the second color conversion layer and the optical cement filled in a plurality of holes of the substrate, respectively, wherein emission wavelengths converted by the first color conversion layer, the second color conversion layer and the optical cement are different, and ratios of widths to heights of the first color conversion layer, the second color conversion layer and the optical cement are between 1:1 and 1:15, and color conversion mixtures used to form the first color conversion layer and the second color conversion layer are cured by excitation light wavelength between 385 nm and 1180 nm; and
wherein a plurality of micro light-emitting diodes disposed under the first color conversion layer, the second color conversion layer and the optical cement are used to provide light to the first color conversion layer, the second color conversion layer and the optical cement,

6. The color conversion structure according to claim 5, wherein the substrate comprises an oxide layer.

7. The color conversion structure according to claim 5, further comprising a reflecting structure disposed on sidewalls of the holes and disposed between the first color conversion layer and the substrate, between the second color conversion layer and the substrate and between the optical cement and the substrate.

8. The color conversion structure according to claim 5. wherein the first color conversion layer and the second color conversion layer comprise a quantum dot material, a photoresist, and a photoinitiator, respectively.

9. The color conversion structure according to claim 5, wherein the optical cement comprises a scattering material, a photoresist, and a photoinitiator.

10. A light-emitting diode display, comprising:
a color conversion structure, wherein the color conversion structure comprises a plurality of color conversion units, and the color conversion units comprise:
a substrate comprising a plurality of holes; and
is a first color conversion layer, a second color conversion layer and an optical cement adjacent to each other, the first color conversion layer, the second color conversion layer and the optical cement filled in the holes of the substrate, wherein the first color conversion layer, the second color conversion layer and the optical cement have different emission wavelengths, and ratios of widths to heights of the first color conversion layer, the second color conversion layer and the optical cement are between 1:1 and 1:15, and color conversion mixtures used to form the first color conversion layer and the second color conversion layer are cured by excitation light wavelength between 385 nm and 1180 nm;
an array of micro light-emitting diodes disposed under the color conversion structure and used to provide light to the color conversion structure; and
a backplane control structure disposed under the color conversion structure and used to control the array of micro light-emitting diodes.
